(19) United States
(12) Patent Application Publication
(10) Pub. No.: US 2012/0027550 A1
(43) Pub. Date: Feb. 2, 2012

(54) AUTOMATED INSTALLATION SYSTEM FOR AND METHOD OF DEPLOYMENT OF PHOTOVOLTAIC SOLAR PANELS

(76) Inventors: John Bellacicco, Stamford, CT (US); Thomas P. Kuster, Clinton, NJ (US); Michael Monaco, Stanhope, NJ (US); Thomas Oshman, Hoboken, NJ (US); John Hartelius, Brick, NJ (US); Henry Cabuhay, Morris Plains, NJ (US)

(21) Appl. No.: 12/846,644

(22) Filed: Jul. 29, 2010

(51) Int. Cl. B60P 1/54; B60P 7/10

(52) U.S. Cl. 414/547; 414/812; 410/34

(57) ABSTRACT

A system of method for automated deployment of a plurality photovoltaic solar panels carried as a unit by a carrier. The system includes an installation trailer, a robot having a mechanism for picking up a carrier and a push actuator. Carriers carrying a plurality of solar panels as a unit may be installed using the system by carrying a plurality of carriers on an installation trailer to a row of rails onto which the carriers are to be installed. The robot picks up each carrier and aligns and places the carrier on the rail system. The push actuator pushes the carrier down the rail system, making space for the next carrier to be installed.

### FIELD OF THE INVENTION

Disclosed embodiments relate to the field of photovoltaic (PV) power generation systems, and more particularly to a system for and method of automated installation of solar panels in large-scale arrays.

### BACKGROUND OF THE INVENTION

Photovoltaic power generation systems are currently constructed by installing a foundation system (typically a series of posts or footings), a module structural support frame (typically brackets, tables or rails, and clips), and then mounting individual solar panels to the support frame. The solar panels are then grouped electrically together into PV strings, which are fed to an electric harness. The harness conveys electric power generated by the solar panels to an aggregation point and onward to electrical inverters.

Prior art commercial scale PV systems such as this must be installed by moving equipment, materials, and labor along array rows to mount the solar panels on the support frames one-at-a-time. This is a time-consuming process, which becomes increasingly inefficient with the scale of the system being installed.

With innovations in solar panel efficiency quickly making PV-generated energy more cost-effective, demand for large-scale PV systems installations is growing. Such systems may have a row length of half a mile or more. Accordingly, a more efficient system for solar panel installation is needed.

### BRIEF DESCRIPTION OF THE DRAWINGS

FIG. 1 is a perspective view showing a carrier.

FIG. 2 is a perspective view showing attachment structures on the underside of a carrier.

FIG. 3 is a perspective view showing mounting carriers to spaced parallel rails.

FIG. 4 is a cross-sectional side view showing an attachment structure for mounting a carrier to a rail.

FIG. 5 is a view showing a magazine being removed from a delivery truck and a view of a tilt table, according to a disclosed embodiment.

FIG. 6 is a view showing a magazine being placed on a tilt table, according to a disclosed embodiment.

FIG. 7 is a view showing operation of the tilt table, according to a disclosed embodiment.

FIG. 8 is a view showing placement of a magazine onto the installation trailer, according to a disclosed embodiment.

FIG. 9 is a view of an installation trailer, according to a disclosed embodiment.

FIG. 10 is a view of a robot, according to a disclosed embodiment.

FIG. 11 is a view of a frame portion of the vacuum system, according to a disclosed embodiment.

FIG. 12 is a view showing a step of operation of the system, according to a disclosed embodiment.

FIG. 13 is a view showing a subsequent step to that shown in FIG. 12 of operation of the system, according to a disclosed embodiment.

FIG. 14 is a view showing a subsequent step to that shown in FIG. 13 of operation of the system, according to a disclosed embodiment.

FIG. 15 is a view showing a subsequent step to that shown in FIG. 14 of operation of the system, according to a disclosed embodiment.

FIGS. 16A-E are views showing operation of the push actuator, subsequent to the step shown in FIG. 15, according to a disclosed embodiment.

FIGS. 17A-B are views of the electrical connections of a carrier, according to a disclosed embodiment.

FIG. 18 is a view showing an attachment structure for mounting a carrier to a rail, according to an additional disclosed embodiment.

FIG. 19 is a block diagram of an alignment system, according to a disclosed embodiment.

FIG. 20 is a block diagram of a computer control system, according to a disclosed embodiment.

FIG. 21 is a perspective view of another embodiment of a carrier.

FIG. 22 is a view showing a mule and wench configuration according to a disclosed embodiment.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein.

Described herein is an automated installation system for deployment of modularly mounted solar panels. The installation system reduces both on-site field labor and equipment movement over the site by providing an automated, mobile installation system for end-of-row, rail-based carrier installation of a plurality of solar panels as a unit. The automated installation system of the disclosed embodiments will have the ability to work in a range of outdoor environments and conditions and at a wide temperature range. The automated installation system may include one or more of a trailer, a robot arm, a pickup device (e.g., a vacuum system) and a push actuator, each of which is described in more detail below.

The automated installation system works in connection with a ground (or roof) mounted rail and carrier system, described in more detail in co-pending application Ser. No. ______, (Attorney Docket no. F4500.1001, entitled MOUNTING SYSTEM SUPPORTING SLIDABLE INSTALLATION OF A PLURALITY OF SOLAR PANELS AS A UNIT, to John Bellacicco, John Hartelius, Henry Cabuhay, Tom Kuster, Michael Monaco and Martin Perkins), filed concurrently with this application, the entire disclosure of which is incorporated herein by reference. A brief description of one embodiment of the rail/carrier system is included herein for completeness and clarity. Other embodiments and configurations of the rail/carrier system are discussed in more detail in the ‘______application (F4500.1001).

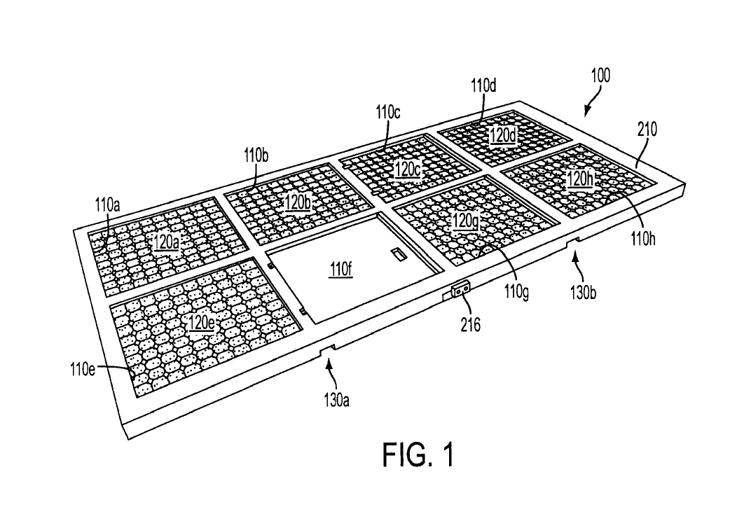

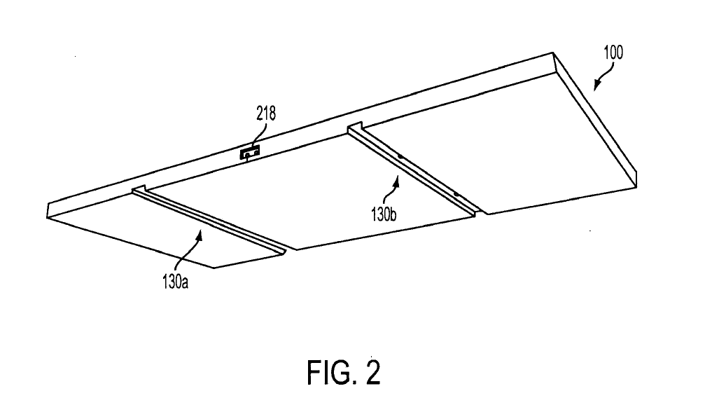

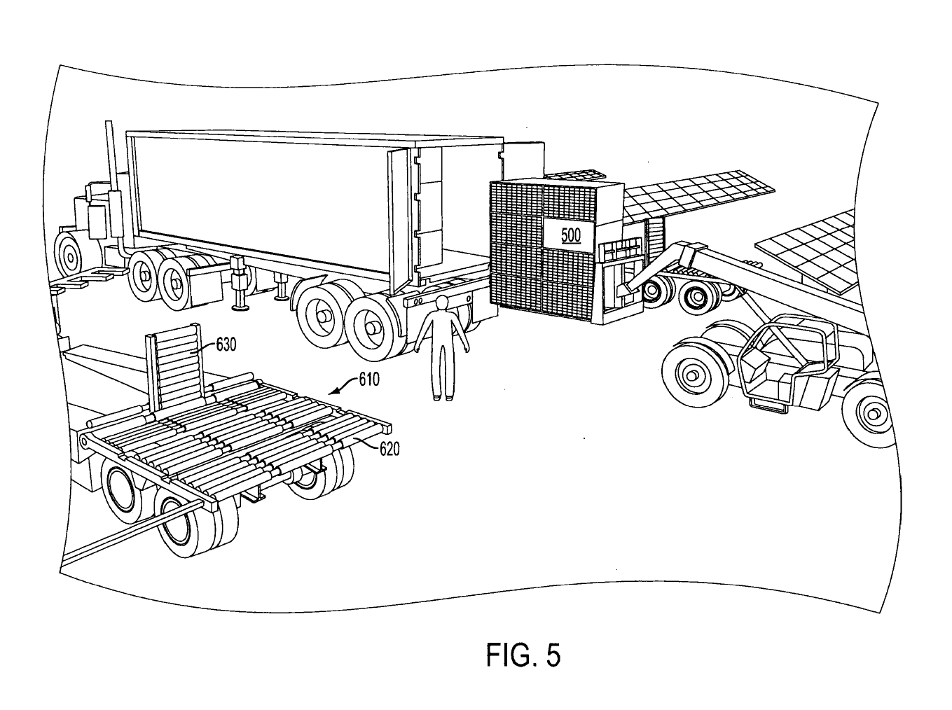

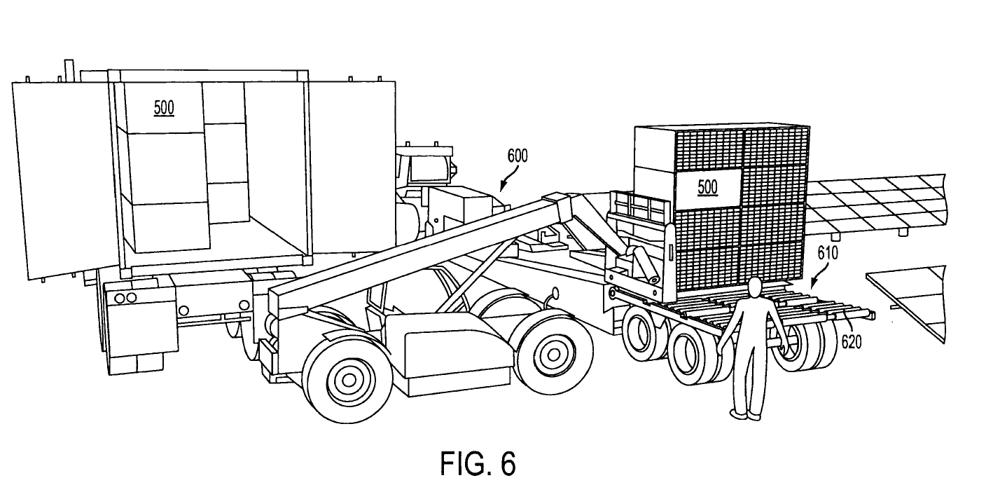

The rail/carrier system is constructed by installing a support structure comprising a plurality of spaced parallel rails mounted to posts that are designed to accept a pre-assembled carrier which acts as a carrier for transporting and mounting a plurality of solar panels as a unit. An exemplary carrier 100 is depicted in FIG. 1. The carrier 100 is a lightweight, cartridge-like structure that provides structural support and contains and supports a plurality of solar panels 120a-h in a 4×2 array and enables their electrical connections. A plurality of solar panels 120a-h are mounted in corresponding recessed areas 110a-h of the carrier 100, with one such recessed area 110f being shown without an installed solar panel in FIG. 1. The solar panels 120a-h are preferably mounted in the carrier 100 during the manufacturing process; thus at the installation site the carrier 100 carrying the plurality of solar panels 120a-h merely needs to be mounted to the rail support structure. The carrier 100 is preferably configured so that regardless of the engagement means used to hold the solar panels 120a-h in place, the solar panels 120a-h are either flush with or below a top surface of the carrier 100. This allows the carrier 100 to be stacked, with other like carriers, for shipping in a specially designed magazine 500 (FIG. 5), which protects the solar panels 120a-h during transit to the installation site. Full details of the engagement means are included in the ‘______ application (F4500.1001).

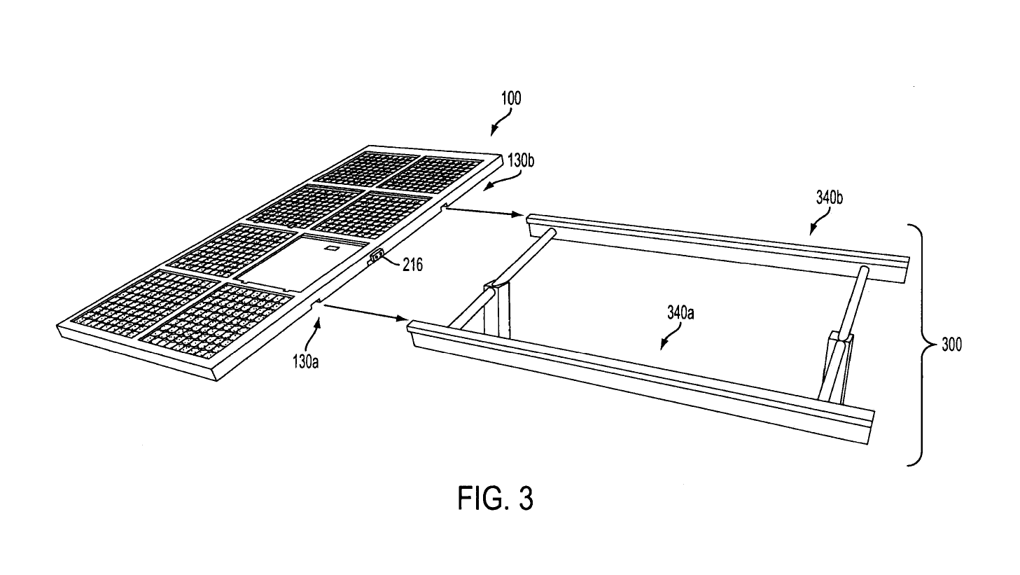

As seen in FIGS. 1-3, each carrier 100 has attachment structures 130a-b to seat the carriers 100 on support structures 300. The support structures 300 generally comprise a set of parallel spaced rails 340a-b. FIG. 2 shows that for carrier 100, the attachment structures are grooves 130a-b in the back side of the carrier 100. Though not shown, the attachment structures could alternatively be located on sidewalls of the carriers 100.

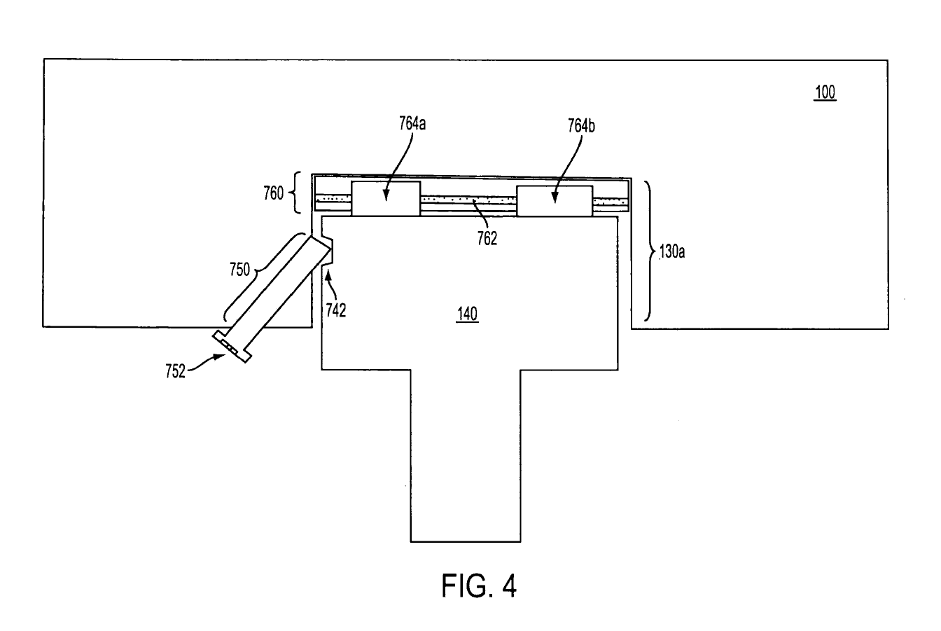

As mentioned above, row length in large-scale PV systems can be half a mile or more. Thus, the carrier 100 should be easily slidable along the parallel spaced rails 340a-b, for ease of carrier 100 installation. FIG. 4 shows an example carrier 100 including a truck 760 mounted within the attachment structure 130a-b, which facilitates easier movement across long stretches of rail 340. The truck 760 comprises of a plurality of paired spaced rollers 764a-b mounted on a corresponding axle 762. The truck 760 only takes up a small portion of space inside the attachment structure 130a-b, so that a T-shaped rail 340a-b can extend far enough in the attachment structures 130a-b to stabilize the carrier 100. In one embodiment, once a carrier 100 is positioned in place, it can be secured to the rails 340 by extending one or more set screws 752 (in channel 750) to engage a groove 742 in the rail 340. Advantageously, the set screw 752 also functions as an electrical ground, grounding the carrier 100, if made of conductive material, to the rail 340. Alternative embodiments of the truck 760 are discussed detail in the ‘______ application (F4500.1001) and in co-pending application Ser. No. ______, (Attorney Docket no. F4500.1005, entitled APPARATUS FACILITATING MOUNTING OF SOLAR PANELS TO A RAIL ASSEMBLY, to John Bellacicco, John Hartelius, Henry Cabuhay, Tom Kuster, and Michael Monaco), filed concurrently with this application, the entire disclosure of which is incorporated herein by reference.

As noted above, carriers 100 are shipped to the installation site in a shipping container in a custom designed magazine 500 (FIG. 5) that stacks the carriers 100 for optimized packaging density and installation efficiency. In order to accommodate stacking for transport as a magazine 500, the carriers 100 are generally designed to stack flatly together and are configured to protect the solar panels 120a-h in the stack and during transit, and the trucks 760 are designed to be completely contained within the grooved attachment structures 130a-b, in order to facilitate stacking. Various embodiments of the carriers 100 configured in such a manner are discussed in detail in the ‘______ and ‘______ applications (F4500.1001, F4500.1005).

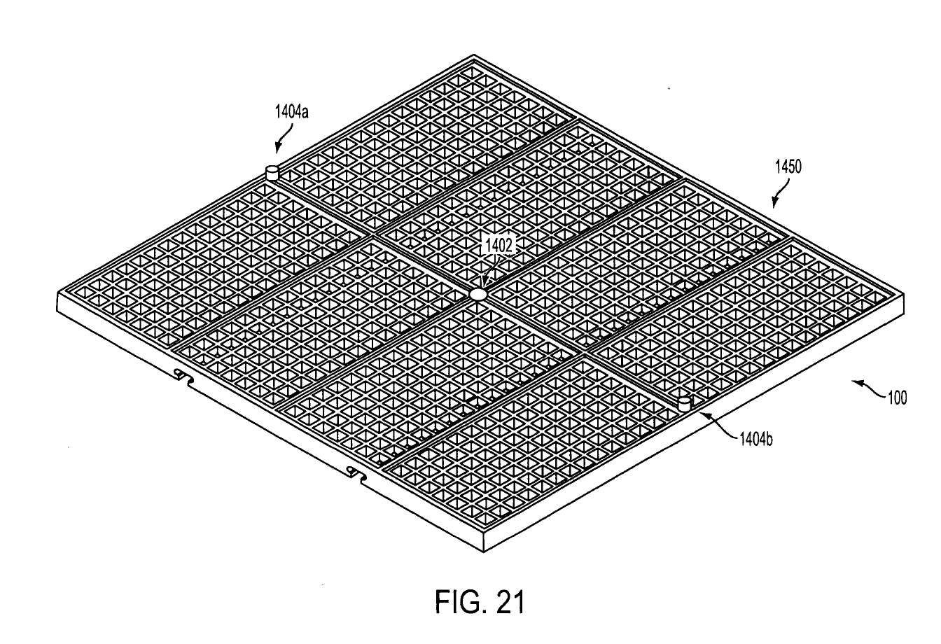

The size of the magazine 500 is designed to be compatible with standard shipping containers, as seen for example in FIG. 5. Each magazine 500 may include, for example, thirty carriers 100. During transport, the magazines 500 are shipped on edge, such that the glass in the solar panels 120a-h is shipped in a vertical orientation. This protects the glass from breakage during shipment. The magazine 500 may be configured either as a physical frame structure that surrounds and holds the stack of carriers 100 or may merely refer to a stack of carriers 100 held together as a group without a separate physical frame. As seen in FIG. 21, in order for the carriers 100 to stay grouped together without a physical frame, a carrier 100 can have one or more openings 1402 so that when carriers are stacked, a threaded securing member (such as for example, a threaded rod) can be inserted in opening 1402 and topped with bolts to ensure the carriers remain secure in place during transit. Carrier 100 may also have a plurality of protrusions 1404a, 1404b to engage corresponding recesses (not shown) in the backside of carrier 1400 to help hold a stack of carriers together as an integrated unit. Alternately, or in addition to the protrusions 1404a, 1404b, and associated recesses, the carrier 1400 can be formed with a self-aligning lip 1450 that engages a corresponding recess (not shown) on the backside of carrier 1400 for the same purpose.

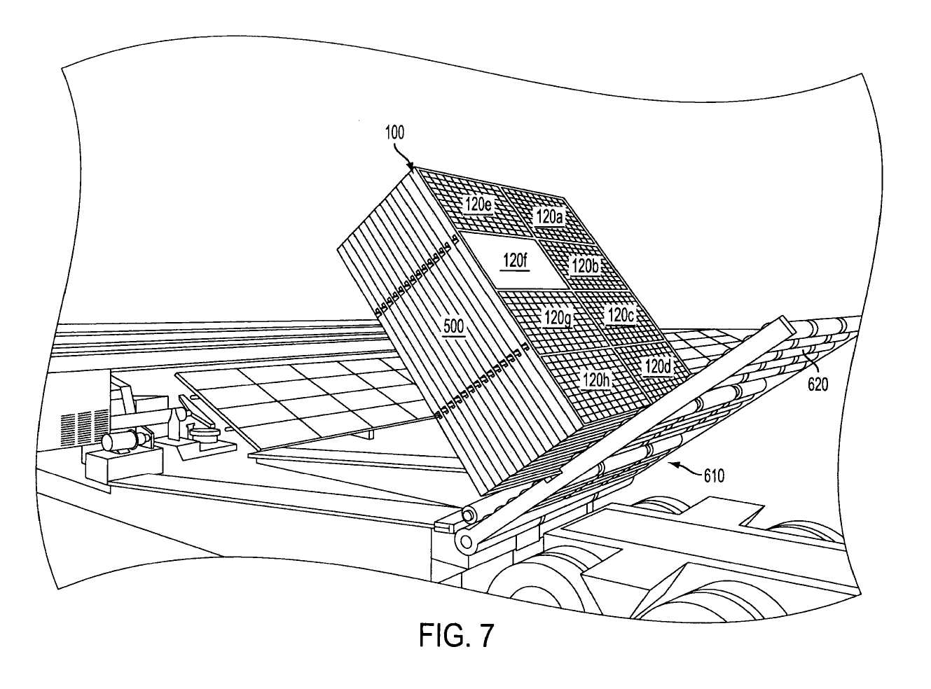

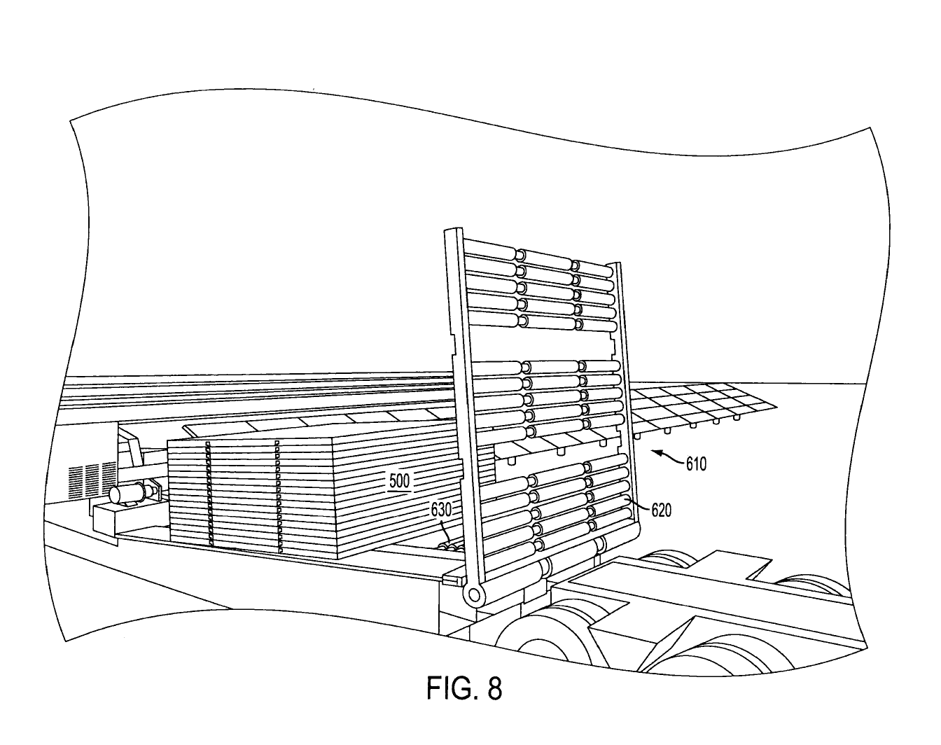

Once on-site, a magazine 500 is unloaded from the shipping container by a forklift, as seen in FIG. 5. The magazine 500 may optionally include furniture glides along a bottom edge of the magazine (when oriented for shipping) and/or a band around the magazine for allowing removal of the magazine 500 from the shipping container without the need for a fork-lift compatible shipping pallet. In this instance, the magazine is slid from the shipping container onto the forklift. The forklift will place the magazine 500 on a tilt table 610 of an installation trailer 600. The tilt table 610 is configured to place the magazine 500 into the appropriate position on the installation trailer 600. This is necessary since, during transport, the magazine 500 is oriented such that the carriers 100 and respective solar panels 120a-h are in a vertical orientation and, during installation, the magazine 500 must be oriented such that the carriers 100 and respective solar panels 120a-h are in a horizontal orientation. In one embodiment, the tilt table 610 includes rollers 620 on the horizontal surface thereof, and another set of rollers 630, perpendicular to the horizontal surface, the two sets of rollers being connected to each other. During operation, the magazine 500 is placed on the horizontal surface rollers 620 from the side of the installation trailer 600, in the same orientation in which it is shipped (FIG. 5), and then the tilt table 610 tilts (along an axis at the connection of rollers 620 and rollers 630) to safely orient the magazine 500 so that the panels 120a-h are in position for installation (FIGS. 7 and 8). Operation of the tilt table 610 may be motorized and may be computer controlled. In another embodiment, the magazine 500 is placed on the horizontal surface rollers 620 of the tilt table 610 from the back of the installation trailer 600. In this embodiment, the tilt table 610 will rotate 90° around a vertical axis to align the magazine 500 appropriately before tilting (along the axis at which rollers 620 connect with rollers 630) to place the magazine 500 into position on the installation trailer 600. Once tilted, the perpendicular rollers 630 are used to slide the magazine 500 forward on the installation trailer 600 to a position near installation robot 400 (described in more detail below). The forklift will obtain and place a second magazine 500 on the installation trailer 600 in the same manner. While the inclusion of only two magazines 500 on the installation trailer 600 at one time is discussed, it should be understood that the invention is not limited as such. Further, during installation, as an entire magazine 500 is installed, the forklift may bring additional magazines 500 to the installation queue on the installation trailer 600.

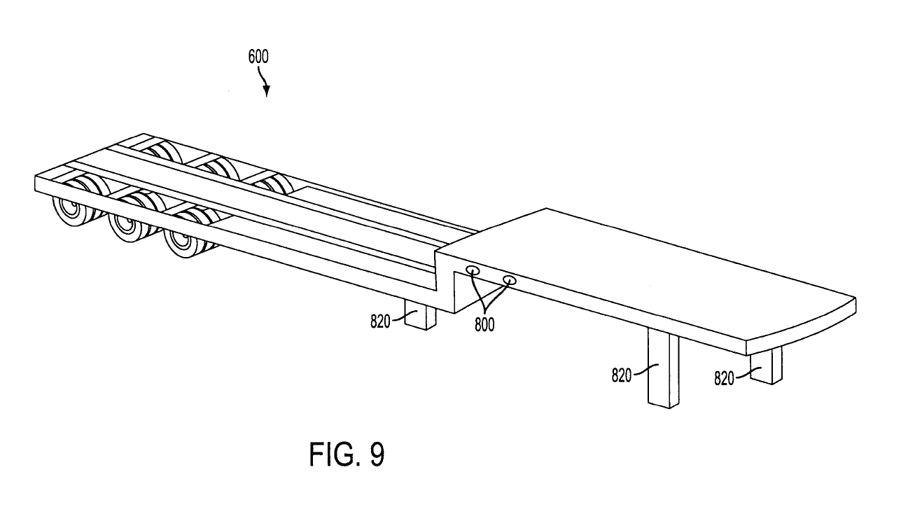

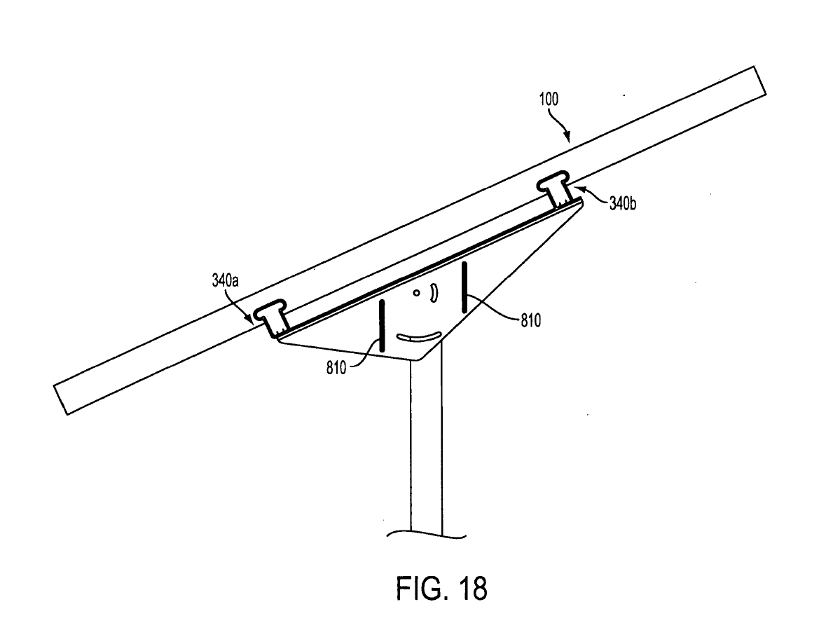

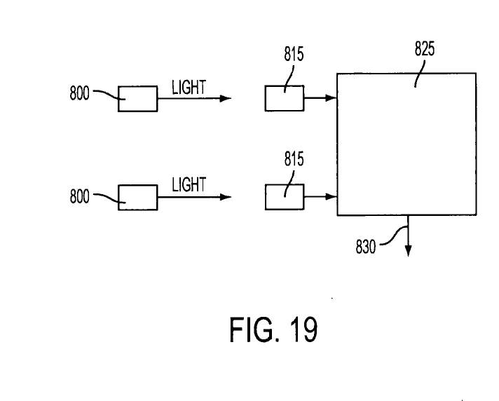

Once loaded with magazines 500, the installation trailer 600 is aligned with the end of the row of rails 340a-b on which the carriers 100 are to be installed. (Alternatively, the trailer 600 may be aligned before magazines are placed on the trailer). Gross alignment of the installation trailer 600 with rails 340a-b is achieved by the driver of the trailer 600. The trailer 600 and/or rails 340a-b include a system to assist the driver in placing the trailer within tolerances of the end of the row, in order to allow automated installation with minimal time for positioning. In one embodiment, the installation trailer 600 and rail system 340a-b may include light sources 800 (seen e.g., in FIG. 9) and markers 810 (seen e.g., in FIG. 18), respectively, which the driver aligns to determine appropriate horizontal alignment. Alternatively, the light source 800 may be located on the rail system 340a-b and the markers 810 located on the installation trailer 600. In another alternative embodiment, as seen in FIG. 19, sharply focused light sources 800, e.g., lasers, and associated light sensors 815 (connected to circuit 825) can be respectively used on the trailer 600 and rail system 340a-b which can provide a visual or audible signal through an electrical current 830 when the two are aligned. Further still, the electrical current 830 may provide feedback to a computer controller within the trailer 600 that uses this information to align the trailer 600 and the rails 340a-b.

One embodiment of the installation trailer is seen in greater detail in FIG. 9. In the example embodiment, the installation trailer 600 is a three-axle, two level trailer. The previously described tilt table 610 may be located at the back end of the trailer (over the wheels) on the lower of the two levels and the robot 400 (described in more detail below) may be located on the upper level. A push actuator 480 (described in more detail below) for pushing the installed carriers 100 along the rails 340a-b is located beneath the upper level, near the robot 400. Alternatively, the tilt table 610, robot 400 and push actuator 480 may all be located on top of the lower level of the installation trailer 600. The installation trailer 600 may also include an additional adjustable mounting system for the robot 400 and or the push actuator 480, to allow these items to be independently adjusted as compared to the rest of the installation trailer 600. This may be important, for example, if the ground is not perfectly level, then the separate adjustable mounting system can ensure the robot 400 and push actuator 480 are level with the rails 340a-b. The installation trailer 600 may also include stanchions 820, which act to stabilize the trailer as well as vertically align the trailer height with the rails.

Before installation of the first carrier 100 onto the rails 340a-b, fine-tune calibration of the robot 400 must be performed to ensure proper alignment with the magazine 500 and the rails 340a-b and proper placement of the carriers 100. This initial fine-tune alignment may be performed manually or by software programming of a computer within the robot 400. Manual alignment is performed by the operator, manually moving the robot arm 410 to touch calibration points on the top carrier 100 of the magazine 500 and on the rails 340a-b. The calibration settings may be stored for use during installation of the entire row of carriers 100. Alternatively, the robot 400 computer may re-calibrate the alignment periodically throughout the installation process of a particular row. The robot 400 computer also includes information regarding the specifications of the carriers 100, such as length, width and thickness, for use in calibration and control of the robot arm 410 and movement of the carriers 100 to the rail system 340a-b. For example, the robot 400 computer includes information regarding the thickness of the carriers 100 so that the decreasing stack height is taken into account during installation of all the carriers 100 in a magazine 500.

Once the installation trailer 600 is in place and the robot 400 has performed the necessary calibration, the individual carriers 100 may be installed on the rail system. In a preferred embodiment, this is done using the specialized robot 400 and vacuum system 430. The operation of the robot arm 410 and vacuum system 430 during installation will be described in detail following the description of each of their configurations.

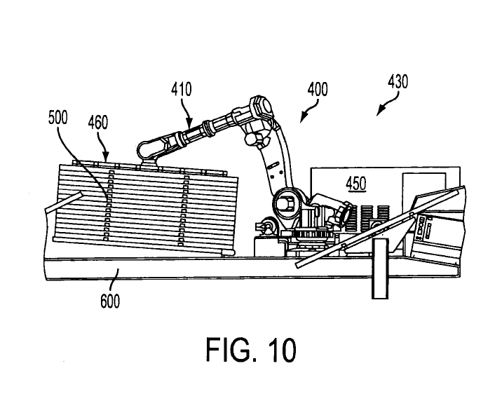

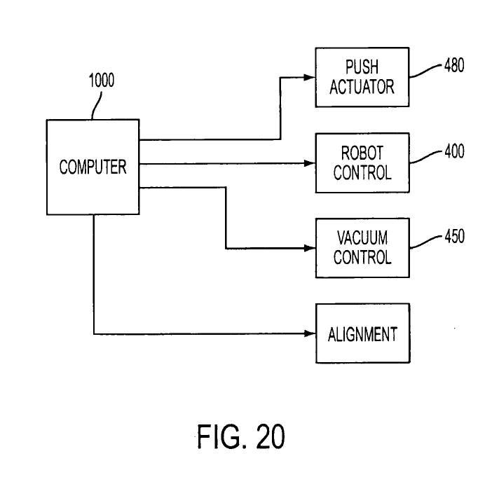

The robot 400, as seen for example, in FIG. 10, is a specially designed robot 400 that includes a robot arm 410 for picking up and moving the carriers 100 from the magazine 500 on the installation trailer 600 to the desired location on the rails 340a-b. In one embodiment, the robot arm 410 has a 3.1 meter (10.1 feet) reach and is capable of carrying 325 kg (716 lb). As noted, the robot 400 includes a computer that utilizes programming and simulation software that direct the robot 400 to perform its necessary functions, including carrier 100 removal and placement, and the alignment calibrations including initial alignment to the magazine 500 and initial alignment to the row. As shown in FIG. 20, a computer 1000 may be utilized to operate not only the robot 400 but also the push actuator 480, the vacuum 450 control and the previously described computer controlled alignment system.

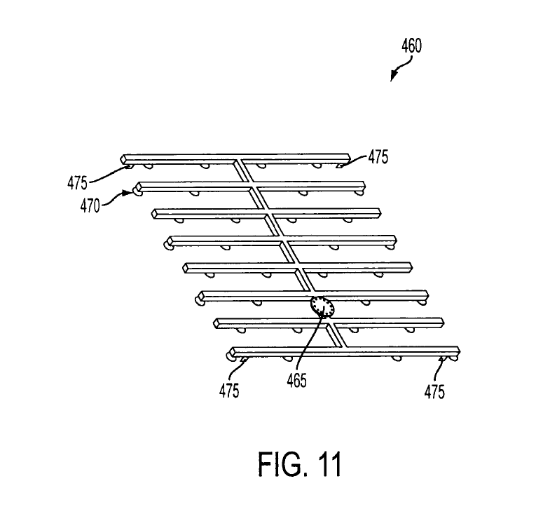

The vacuum system includes an extruded aluminum frame 460, shown in FIG. 11, that attaches to the end of the robot arm 410 at attachment point 465. The frame 460 includes suction cups 470 for attaching to and lifting the solar panels 120a-h. In one preferred embodiment, the frame 460 may include 32 suction cups 470 (e.g., four per solar panel), each of which is 3.3 inches in diameter. The suction cups 470 may be formed of vinyl. The frame 460 may also include only one suction cup 470 per solar panel 120a-h in the carrier 100, for example, eight suction cups 470. It should be understood however, that any number of suction cups 470 may be used for attaching to and lifting the solar panels 120a-h mounted on a carrier 100 as a unit, as would be recognized by one of skill in the art.

In one embodiment, the frame 460 may also include extensions 475 that extend from the frame 460. These extensions 475 prevent the suction cups 470 from sliding along the panels 120a-h. In another embodiment, the extensions may also be configured such that a portion extends beneath the carrier 460 in order to provide a backup in case a vacuum loss occurs, thus preventing the carrier 100 from falling. The extensions 475 may be configured such that they are movable so that they may be extended after picking up the carrier 100 and release when the carrier 100 is set in place, if desired.

The suction cups 470 are connected to a vacuum source 450. In one embodiment, the vacuum source 450 may provide 20″ Hg of suction with 20 SCFM (standard cubic feet per minute). The conservative lifting force of the vacuum should be approximately 1800 pounds. Additionally, in one preferred embodiment, the vacuum 450 may include a vacuum switch to detect whether or not a carrier 100 is present and also to confirm that no leaks are occurring in the vacuum system 430.

The vacuum source 450 may be, for example, a compressed air and a venturi style manifold system to produce a vacuum. In embodiments including this type of vacuum source 450, two manifold pumps are provided, each supplying a vacuum to half of the suction cups 470 on the frame 460 (e.g., 16 in a 32 suction cup embodiment). One benefit of this type of vacuum system is that if one pump manifold fails or begins to leak, the other is there as a backup, supplying a vacuum to the other half of the suction cups 470. If a power loss were to occur, this type of system keeps suction for a short period of time, preventing an immediate loss of vacuum, which would result in dropping the carrier 100. Another benefit of the compressed air/manifold vacuum system is that the air flow can be rerouted through a solenoid, allowing an air blow-off to occur. This air blow off could be used, for example, to blow debris or water from the solar panels 120a-h before enabling the vacuum and/or to enable rapid release of the suction cups 470 from the carrier 100 after installation.

The vacuum source 450 may be, alternatively for example, a rotary vane style vacuum pump. In embodiments including this type of vacuum source 450, a vacuum pump is directly connected to all of the suction cups 470 on the frame 460. This type of system is not as complex as the compressed air/manifold vacuum system and requires fewer components. Additionally, a vacuum pump has a relatively small footprint (as compared to a compressor system) and consumes approximately half the amount of power as the compressed air and a venturi style manifold system.

As would be apparent to one skilled in the art, each of these vacuum sources 450 has particular advantages and disadvantages with respect to its use in the vacuum lift system 430. Either of the described vacuum sources 450, or another appropriate vacuum source 450 as determined by one of skill in the art, may be used with the vacuum lift system 450 of the automated installation system of the preferred embodiments.

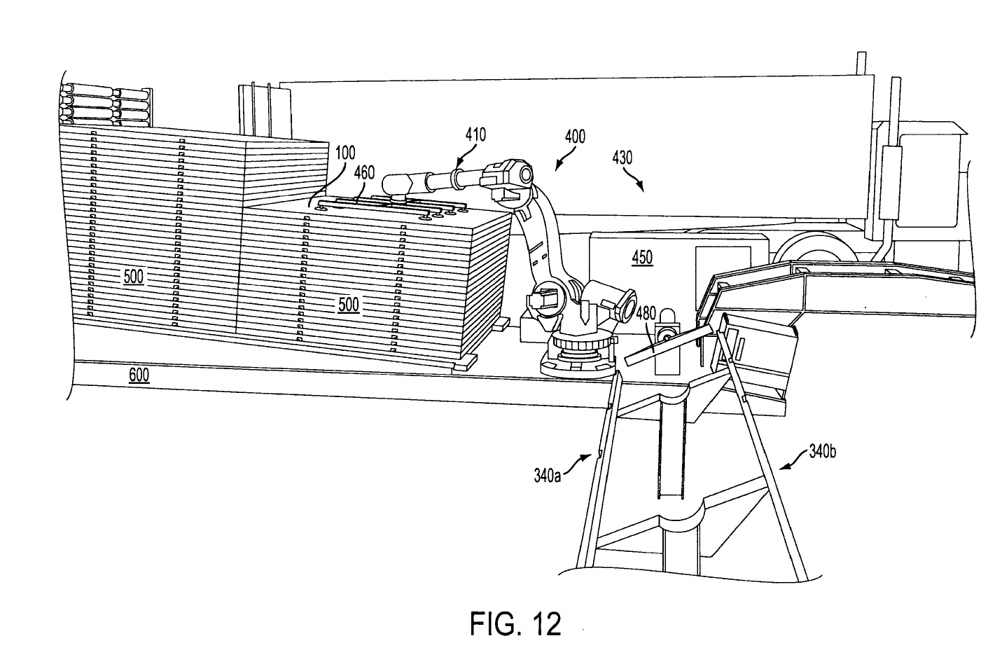

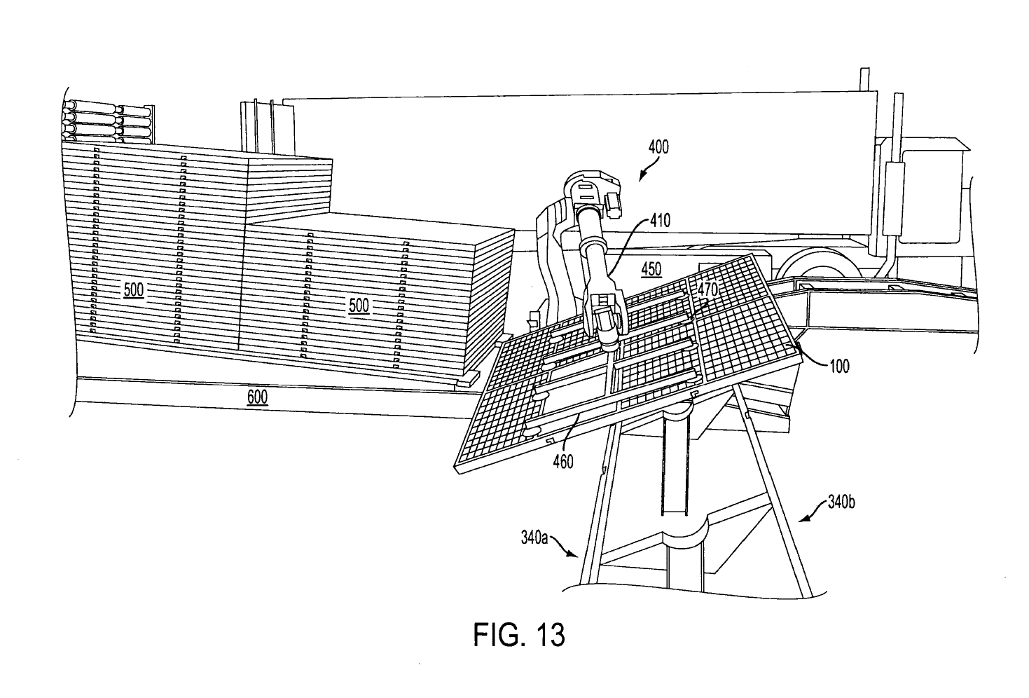

During operation, the robot arm 410, to which the frame 460 of the vacuum system 430 is attached, moves to align the frame 460 over the first carrier 100, situated as the top carrier 100 in the magazine 500, as shown in FIG. 12. Once aligned, the vacuum is activated and the suction cups 470 are engaged with the solar panels 120a-h of the carrier 100. In one embodiment, the vacuum system 430 emits a puff of air from the suction cups 470 before the vacuum is activated, in order to clean the glass of the solar panels 120a-h to enhance suction of the suction cups 470. As seen in FIG. 13, the robot arm 410 the lifts the carrier 100 off the magazine 500 (and, if applicable, the frame extensions extend to hold the carrier 100 in place during movement) and moves the carrier 100 over to the rail system 340a-b.

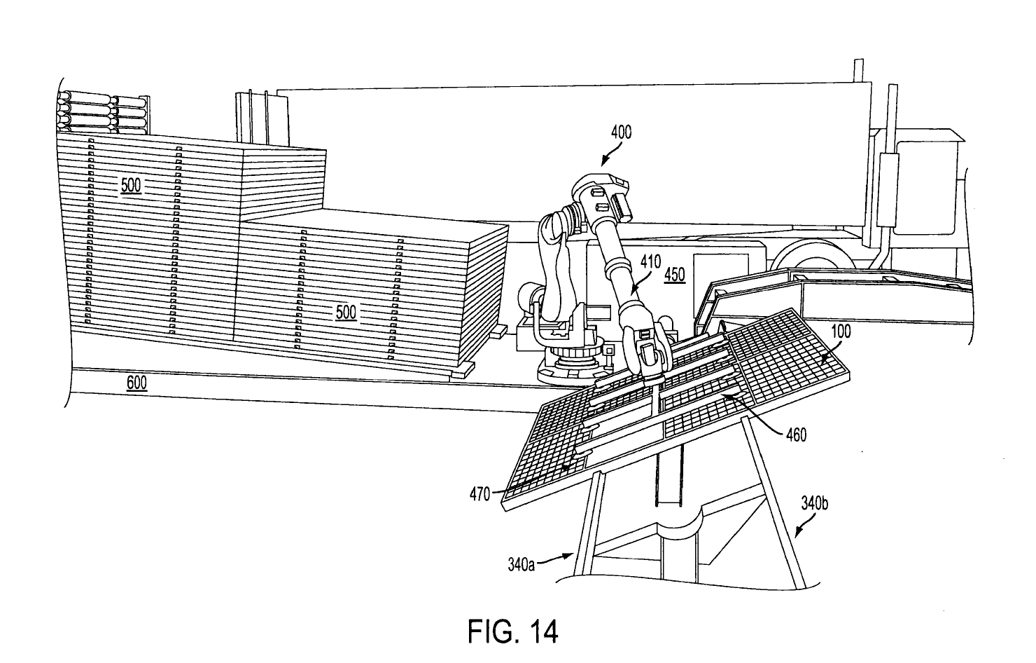

As shown in FIG. 14, the carrier 100 is placed onto the rail system 340a-b from above. It should also be noted that while the carrier 100 is lifted in a horizontal position, that the carrier 100 is rotated at an angle to match the angle of the rails 340a-b (e.g., an angle of 45° from horizontal) before being placed on the rails 340a-b. As previously described, the carrier 100 and rail system 340a-b are designed to be compatible and such that the carrier 100 is easily slidable along the rails 340a-b. Depending on the particular configuration of the rail/carrier system, the carrier 100 may not be able to be placed onto the rail system 340a-b from above. For example, if the rails 340a-b have a generally T-shaped cross-section, as seen for example in FIG. 18, it may be necessary to slide the carrier 100 onto the rails 340a-b from the end of the row. Alternatively, the rails 340a-b may include a portion near the end of the rails that is configured without the cross portion of the T-shaped rail, such that the carrier 100 may be placed onto the rails 340a-b from above and then slid onto the T-shaped portion of the rail.

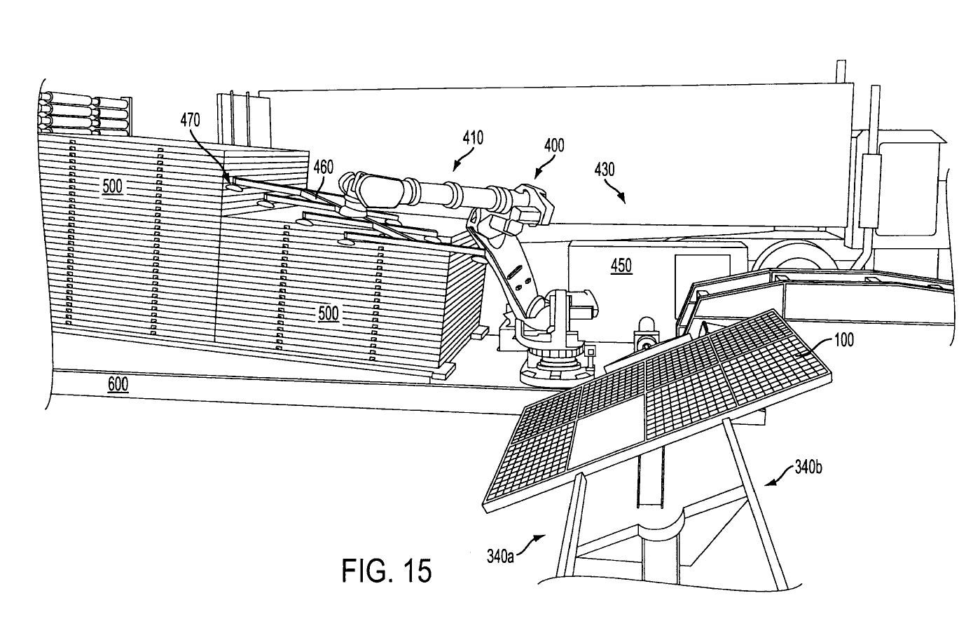

Once the carrier 100 is in place, the vacuum is deactivated and the carrier 100 is released onto the rails 340a-b, as seen in FIG. 15. In one embodiment, the vacuum emits a puff of air to allow quick release of the suction cups 470 from the solar panels 120a-h to release the carrier 100. The robot arm 410 returns to retrieve the next carrier 100 for installation.

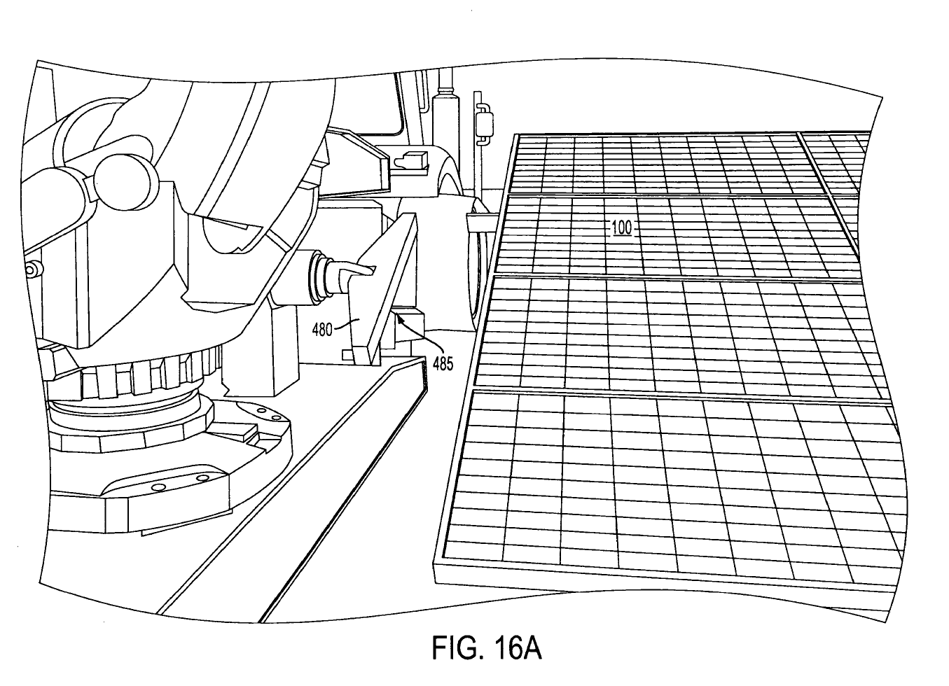

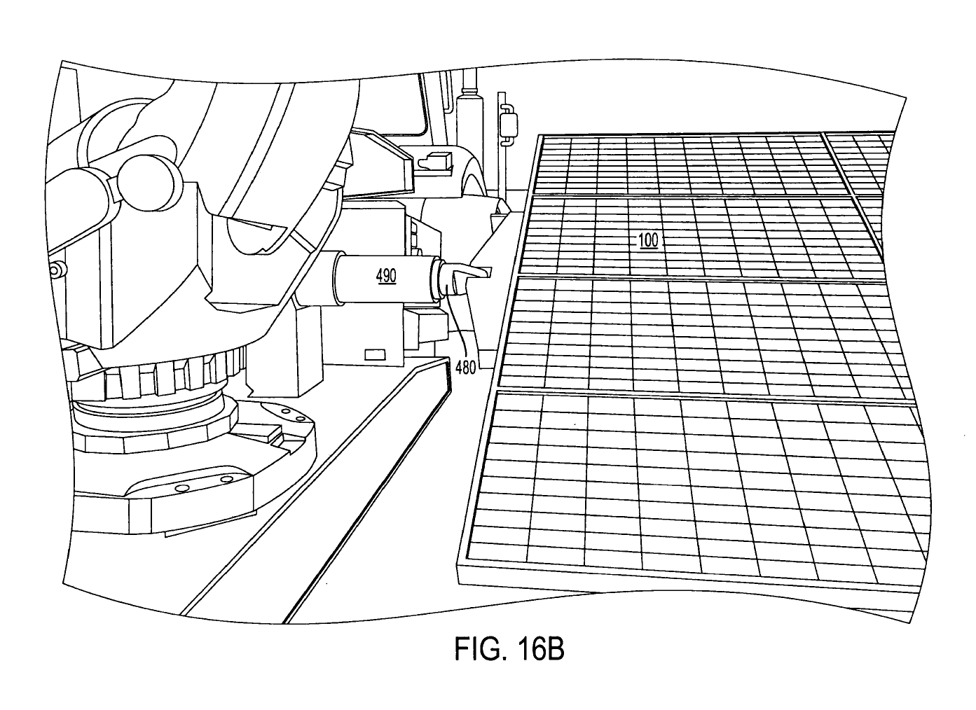

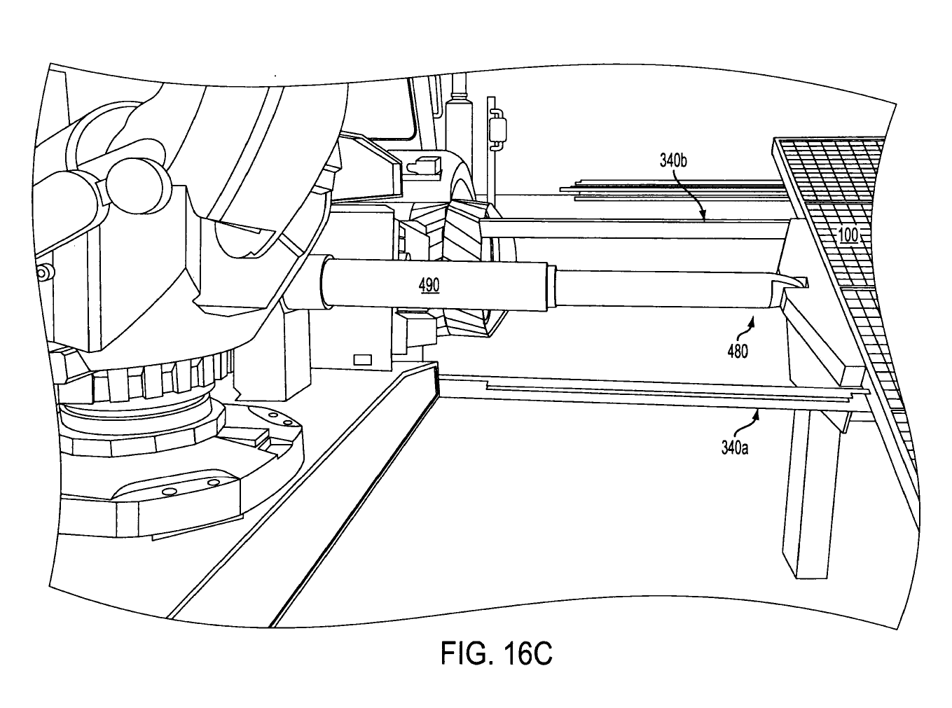

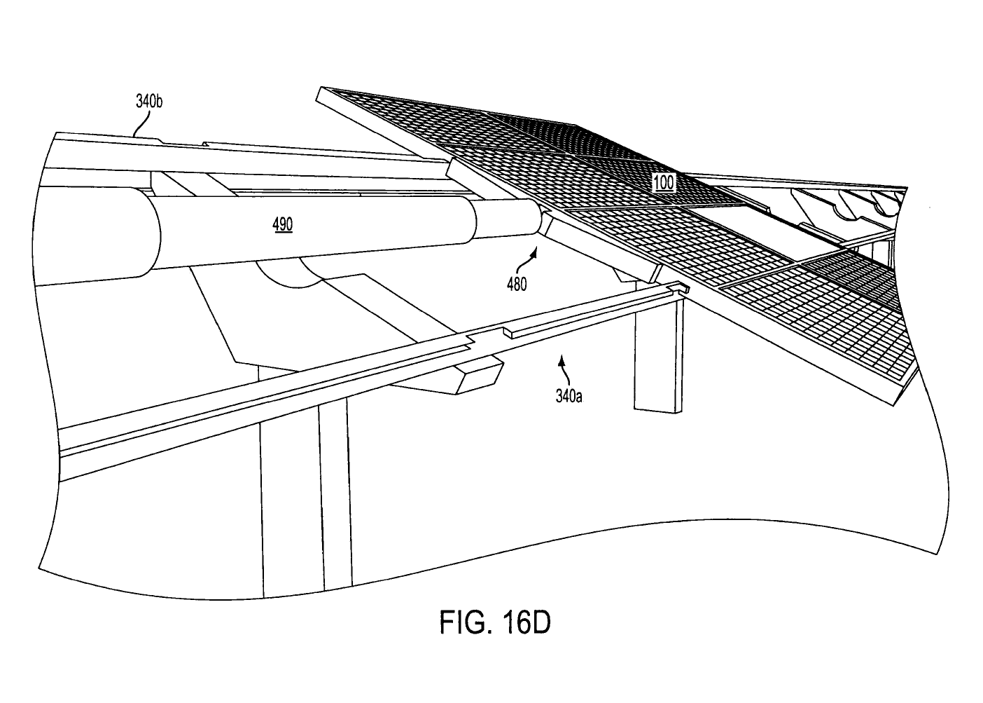

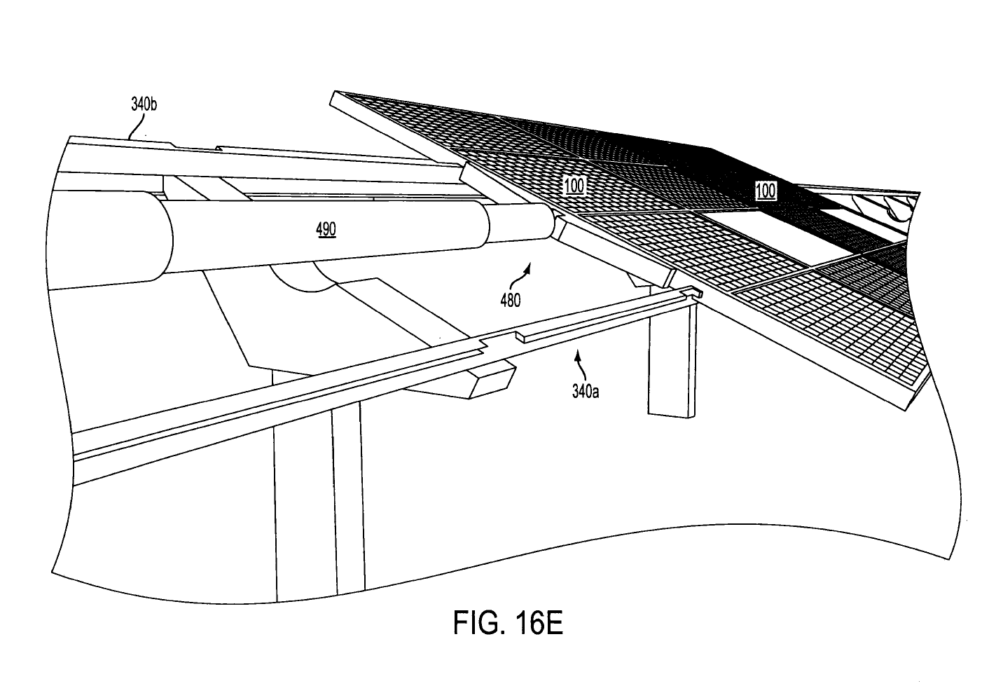

As seen in FIGS. 16A-E, once a carrier 100 is placed on the rails 340a-b, a push actuator 480 pushes the carrier 100 down the rails 340a-b. As best seen in FIG. 16A, the push actuator 480 has a flat surface 485 to engage the edge of the carrier 100. A telescoping arm 490 extends to press the carrier 100 down the rails 340a-b (FIGS. 16B-D). As seen in FIG. 16E, the push actuator 480 may be configured to push more than one carrier 100 at a time, in order to install a plurality of carriers 100 onto the rail system 340a-b from the installation trailer 600 location at the end of the row.

In order to prevent carriers 100 from being pushed off the opposite end of the rail system 340a-b, the push actuator 480 must be able to distinguish how far to push the carriers 100. This is important from both an operation and safety perspective. This may be accomplished by a variety of methods. In one embodiment, the robot computer also monitors and controls the operation of the push actuator 480 with the computer being capable of monitoring how far push actuator 480 has pushed the carriers 100 down the rail system 340a-b of a particular row. Once this distance is equal to a known row length, the push actuator 480 stops pushing. In another embodiment, the robot computer keeps track of how many carriers 100 have been installed on the row and only installs as many carriers 100 per row as a preset number stored in the computer. In another embodiment, the push actuator 480 computer senses a preset max pushing force at the actuator 480, which may, for example, be the force required to push the maximum number of carriers 100 down the row. When the required pushing force is above this max pushing force, the computer controls the push actuator 480 so it stops pushing. This embodiment not only saves the push actuator 480 from pushing the carriers 100 off the end of the rails 340a-b, but also prevents continued pushing if a carrier 100 were to get stuck on an obstruction on the rails 340a-b. Alternatively, the computer can control push actuator 480 such that it stops pushing if the carriers 100 are no longer moving.

As an alternative to using the push actuator to push the carriers 100 down the rail system a mule and wench system could be used to pull the carriers 100 down the row. As seen in

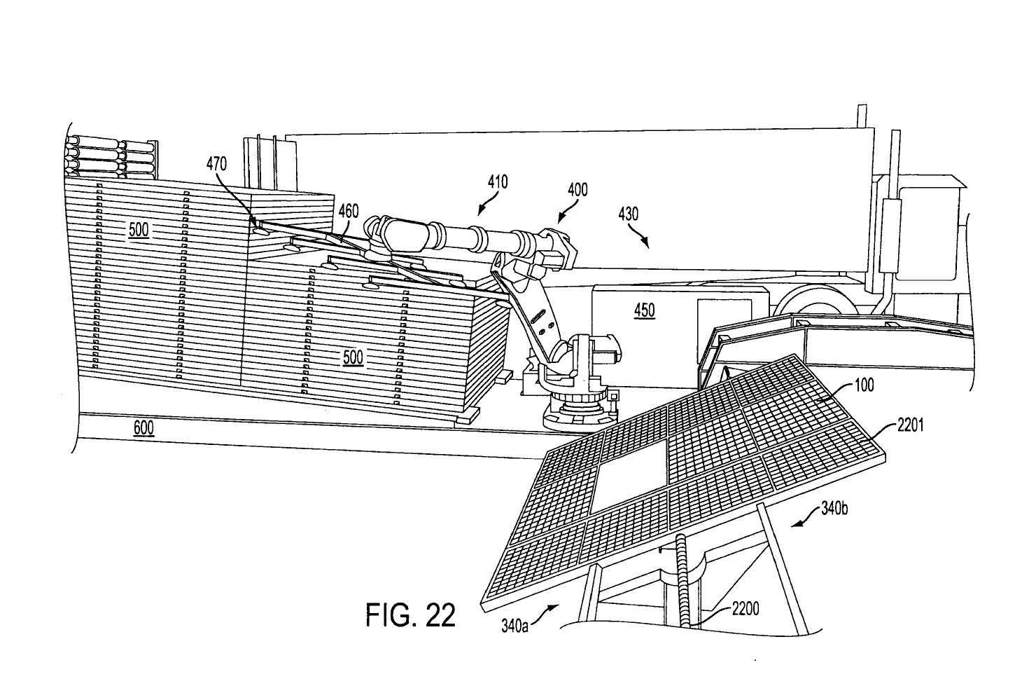

FIG. 22, a mule 2201 (which may or may not contain solar panels) is installed on the rail system prior to installation of the carriers 100. This mule 2201 includes an attachment for wench 2200, which pulls the mule 2201 down the rail system. As each carrier 100 is installed onto the rails 340a-b, the newly installed carrier 100 is connected to the mule 2201 (if it is the first carrier 100 to be installed) or to the previously installed carrier 100 (for subsequent carriers 100). In this way, when the mule 2201 is pulled down the rail system by wench 2200, it pulls the installed train of carriers 100 along with it.

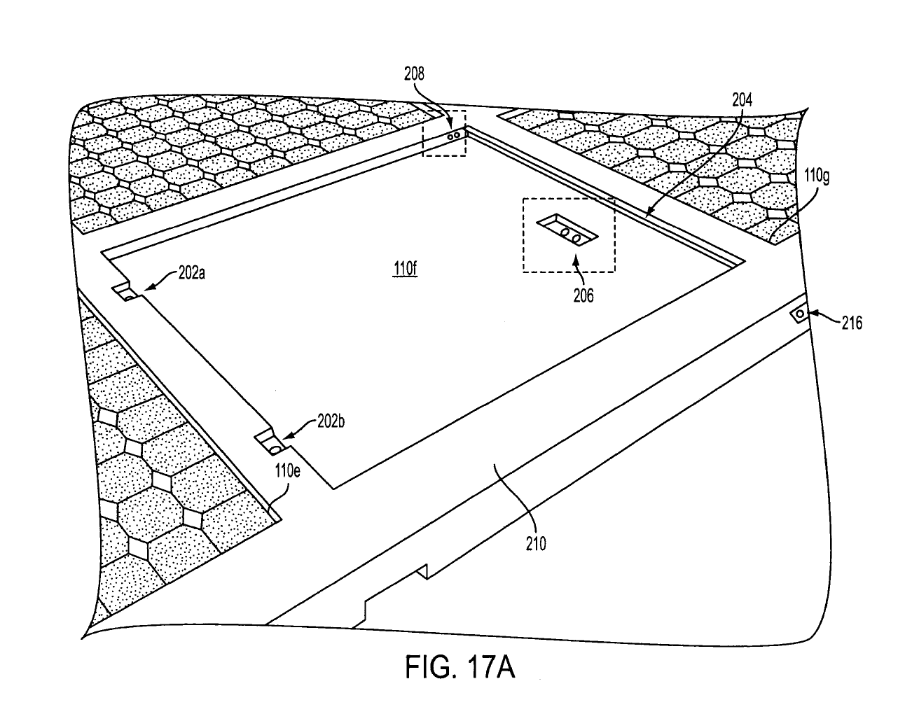

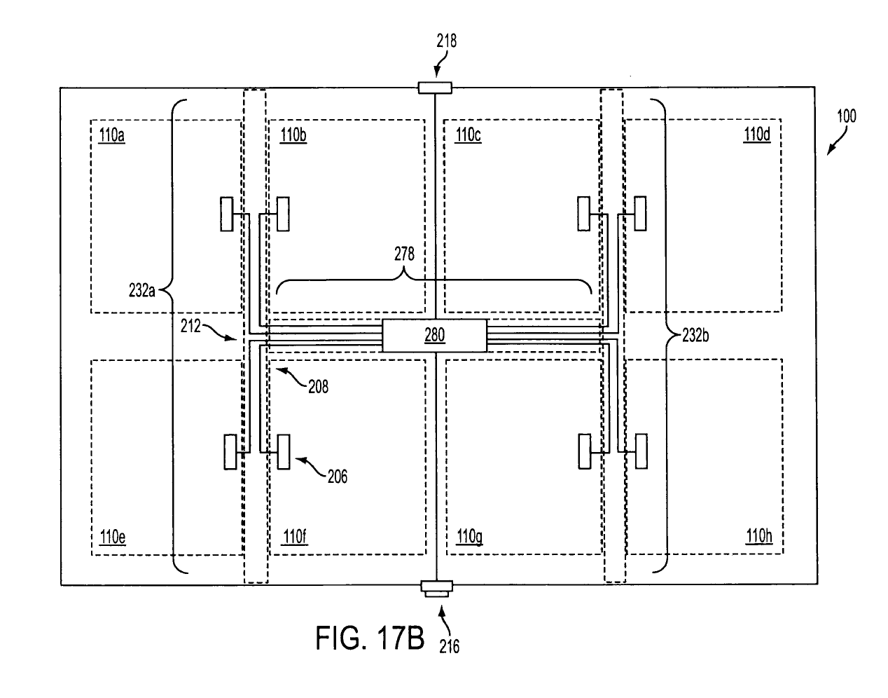

In general, PV-generated electricity is harvested and transmitted through a pre-wired common bus or cable system integral to the carrier 100. Some examples of a common bus system that may be employed are described in more detail in co-pending application Ser. No. ______, (Attorney Docket no. F4500.1004, entitled APPARATUS FACILITATING WIRING OF MULTIPLE SOLAR PANELS, to John Bellacicco and Siddika Pasi), filed concurrently with this application, the entire disclosure of which is incorporated herein by reference. One embodiment of pre-wiring a carrier 100 for connection to a common bus system 280 is shown in FIGS. 17A-B. As shown in FIG. 17A, an electrical connector 206 can be provided in the lower surface of the recessed area 110f so that when the solar panel 120f is placed in a recessed area 110f, a plug on the bottom of the solar panel 120f engages electrical connector 206 to connect it to the common bus system 280. FIG. 17A also shows electrical connectors 208 provided in a sidewall of the recessed areas 110f that could be used in lieu of connector 206 to connect wiring 212 to side electrical connectors on a solar panel 120f. An exemplary electrical connection schematic for a carrier 100 is shown in FIG. 17B.

As shown in FIG. 17B, the wiring 212 runs from the electrical connectors 206 in each recessed area 110a-h into a channel 132a-b provided in carrier 100 which run above each attachment area 130a-b. Each of the channels 132a-b is connected to a transverse central channel 278 which runs through carrier 100, which houses the common bus system 280. The wiring 212 connects electrical connectors 206, and thus the solar panel 120a-h engaged in each recessed area 110a-h, to the common bus system 280. Although the common bus system 280 in each carrier 100 can be terminated at an electric harvester on the support structure (as described in the ‘______ application (F4500.1001)), FIG. 17B shows an embodiment where each carrier 100 can be equipped with a male electrical connector 216 and female electrical connector 218 for interconnecting the common bus systems of multiple carriers 100 together. In this manner, as the carriers 100 are slid into position on a support structure in the manner discussed above and pressed against each other, corresponding male 216 and female 218 connectors engage to electrically connect the solar panels 120a-h carried by adjacent carriers 100. Interconnected carriers 100 can then transfer electric power to a common point and onward to an electrical inverter before connecting to an electrical grid.

Once an entire row of carriers 100 has been installed on the rails 340a-b of one row, the installation trailer 600 is moved to the next row of rails 340a-b and the entire process is repeated. As previously noted, at any time during the installation process, as the magazines 500 of carriers 100 are installed, additional magazines 500 may be brought to the installation trailer 600, as described above.

As opposed to the labor intensive installation methods currently used, the automated installation system of the preferred embodiments will be able to work, for example, 20 hours per day, 7 days per week (there is still a requirement of some maintenance time on the system). The automated installation system of the preferred embodiments will have the ability to work in a range of outdoor environments and conditions (e.g., hot, cold, windy, snowy, etc.), and at a wide temperature range (−30° F. to 120° F.) and at wind gusts up to 50 miles per hour. Further, the automated installation system of the preferred embodiments is able to achieve an average installation velocity, for example, of less than one minute per carrier 100 (including installation cycle time and system setup time). The automated installation system will increase the rate of panels installed per hour, while decreasing the logistics and system maintenance. The automated installation system of the preferred embodiments allows a significant reduction of installation costs of solar panels and a significant reduction in the time to online operation.

While the disclosed embodiments show the installation of carriers containing a plurality of solar panels, the installation system described herein may also be used to install carriers containing only a singular solar panel. Additionally, while the disclosed embodiments show the installation of carriers on a ground mounted rail system, the installation system described herein may also be used for smaller scale installations, such as on a roof. The installation system described herein may also be used for installing solar panels onto a movable mount tracker-type system.

While embodiments have been described in detail, it should be readily understood that they are not limited to the disclosed embodiments. Rather the embodiments can be modified to incorporate any number of variations, alterations, substitutions or equivalent arrangements not heretofore described.

What is claimed as new and desired to be protected by Letters Patent of the United States is:

1. An installation system for installing at least one carrier, each carrier carrying a plurality of photovoltaic solar panels as a unit onto a corresponding rail system, the system comprising:
an installation trailer including a surface for accommodating the at least one carrier;
a robot installed on the installation trailer, the robot including a robot arm for moving the at least one carrier to the rail system; and
a pickup device for picking up the at least one carrier, the pickup device being connected to the robot arm.

2. The system of claim 1, further comprising a push actuator installed on the installation trailer for pushing the at least one carrier along the rail system.

3. The system of claim 1, wherein the installation trailer further comprises an upper and lower level, wherein the robot and pickup device are installed on the upper level of the installation trailer.

4. The system of claim 2, wherein the push actuator is installed beneath the upper level of the installation trailer.

5. The system of claim 1, wherein the robot is a computer controlled robot programmed to align the pickup device with the at least one carrier, and move the carrier to the rail system.

6. The system of claim 5, wherein the robot is further programmed to perform alignment calibration of the robot arm and pickup device to a magazine containing a plurality of carriers and to the rail system.

7. The system of claim 1, wherein the pickup device comprises a vacuum system comprising a frame attached to the robot arm, a plurality of suction cups attached to the frame for engaging with the solar panels and a vacuum source providing a vacuum to the plurality of suction cups, the plurality of suction cups and vacuum acting to lift the at least one carrier.

8. The system of claim 7, further comprising one suction cup corresponding to each of the plurality of solar panels in the at least one carrier.

9. The system of claim 7, further comprising a plurality of suction cups corresponding to each of the plurality of solar panels in the at least one carrier.

10. The system of claim 7, wherein the vacuum source comprises a venturi style manifold system for providing a vacuum to said plurality of suction cups.

11. The system of claim 7, wherein the vacuum source comprises a rotary vane vacuum pump for providing a vacuum to said plurality of suction cups.

12. The system of claim 7, wherein the vacuum provided by the vacuum source has a lifting force of approximately 1800 pounds.

13. The system of claim 7, wherein the frame of the vacuum system further comprises extensions for holding the carrier in place during movement.

14. The system of claim 2, wherein the push actuator further comprises a telescoping arm.

15. The system of claim 1, further comprising a mechanism for holding a plurality of carriers in a group.

16. The system of claim 15, wherein the mechanism for holding a plurality of carriers in a group is a magazine for containing a plurality of carriers.

17. The system of claim 16, wherein the installation trailer accommodates at least two magazines.

18. The system of claim 1, wherein the installation trailer further comprises a tilt table for orienting a plurality of held together in a group.

19. The system of claim 18, wherein the tilt table comprises a plurality of rollers arranged to provide two surfaces, the two surfaces being connected at an approximately 90 degree angle relative to each other and wherein the tilt table is installed on the installation trailer such that it is rotatable around an axis formed along the connection between the two surfaces.

20. The system of claim 19, wherein the tilt table is further rotatable around a vertical axis perpendicular to an upper surface of the installation trailer.

21. The system of claim 1, wherein the installation trailer and rail system each further comprise one of lights and alignment marks, wherein alignment is facilitated by matching up the lights with alignment marks, for horizontal alignment of the installation trailer to the rails.

22. The system of claim 1, wherein the installation trailer and rail system each further comprise one of lights and light sensors, and the system further comprises computer programmed to control alignment of the installation trailer based on signals received from the light sensors.

23. The system of claim 1, wherein the installation trailer further comprises a mechanism that allows for vertical alignment of the installation trailer to the rails.

24. A method of automated installation of a plurality of carriers, each carrying a plurality of photovoltaic solar panels as a unit, onto a corresponding rail system, the method comprising:
providing a set of grouped together carriers comprising at least a portion of the plurality of carriers at the end of a rail system onto which the carriers are to be installed;
aligning a pickup system at the end of the rail system onto which the carriers are to be installed;
aligning a frame of the pickup system with a top carrier in the set of grouped together carriers;
picking up one of the carriers;
moving the carrier to the rail system;
placing the carrier onto the rail system; and
moving the carrier along the rail system.

25. The method of claim 24, wherein the pickup system comprises a plurality of suction cups arranged on the frame and attached to a vacuum source, wherein the frame is aligned with the top carrier such that the suctions cups are adjacent the solar panels of the carrier.

26. The method of claim 25, wherein picking up the carrier comprises activating the vacuum source to create a vacuum to engage the suction cups with the carrier and lifting the carrier.

27. The method of claim 24, wherein the set of grouped together carriers are held in a magazine.

28. The method of claim 24, wherein each of the steps of aligning the frame, picking up the carrier, moving the carrier, placing the carrier and moving the carrier is repeated for each carrier in the set of grouped together carriers.

29. The method of claim 24, wherein the set of grouped together carriers are placed on an installation trailer for installation transport to the installation location and the pickup system is installed on the installation trailer, and
wherein aligning the pickup system comprises alignment of the installation trailer to the rail system on which the carriers are to be installed.

30. The method of claim 29, wherein alignment of the installation trailer to the rail system comprises aligning lights attached to one of the installation trailer and the rail system with alignment marks provided on the other of the installation trailer and the rail system.

31. The method of claim 30, wherein alignment of the installation trailer is computer controlled.

32. The method of claim 24, wherein the steps of aligning the frame, picking up the carrier, moving the carrier and placing the carrier are accomplished by a computer controlled robot.

33. The method of claim 26, wherein prior to activating the vacuum source, a puff of air is emitted from the suction cups to clean a surface of the carrier.

34. The method of claim 24, wherein before placing the carrier onto the rail system, the carrier is tilted to an angle to match an angle of the rail system.

35. The method of claim 26, wherein after placing the carrier onto the rail system, the vacuum source is deactivated to release the carrier.

36. The method of claim 24, wherein moving the carrier comprises pushing the carrier down the rail system using a telescoping push actuator.

37. The method of claim 24, wherein moving the carrier comprises pulling the carrier down the rail system using a wench.

38. The method of claim 24, further comprising electrically connecting a subsequently installed carrier to an adjacent, previously installed carrier.

39. The method of claim 38, wherein the adjacent carriers are electrically connected by sliding into one another on the rail system.

40. An installation system for installing at least one carrier, each carrier carrying at least one solar panel, onto a corresponding rail system, the system comprising:
an installation trailer including a surface for accommodating the at least one carrier;
a robot installed on the installation trailer, the robot including a robot arm for moving the at least one carrier to the rail system;
a pickup device for picking up the at least one carrier, the pickup device being connected to the robot arm; and
a moving device for moving the at least one carrier along the rail system.

41. A method of automated installation of a plurality of carriers, each carrying at least one solar panel, onto a corresponding rail system, the method comprising:
providing a set of grouped together carriers comprising at least a portion of the plurality of carriers at the end of a rail system onto which the carriers are to be installed;
aligning a pickup system at the end of the rail system onto which the carriers are to be installed;
aligning a frame of the pickup system with a top carrier in the set of grouped together carriers;
picking up the carrier;
moving the carrier to the rail system;
placing the carrier onto the rail system; and
moving the carrier along the rail system.

42. The method of claim 41, wherein each of the steps of aligning the frame, picking up the carrier, moving the carrier, placing the carrier and moving the carrier is repeated for each carrier in the set of grouped together carriers.

43. A shipping magazine for shipping photovoltaic solar panels, the shipping magazine comprising:
a structure for supporting a plurality of carriers, each carrier carrying at least one photovoltaic solar panel,
wherein the carriers are configured to stack flatly against each other within the magazine.

44. The shipping magazine of 43, wherein each carrier carries a plurality of solar panels.

45. A plurality of carriers, each carrying a plurality of photovoltaic solar panels as a unit, held together as a group in a stack.

46. The plurality of carriers of claim 45, wherein the plurality of carriers are held together by a frame surrounding the plurality of carriers.

47. The plurality of carriers of claim 45, wherein the plurality of carriers are held together by a band surrounding the plurality of carriers around a perimeter of the stack.

48. The plurality of carriers of claim 45, wherein the plurality of carriers are held together by at least one threaded rod inserted into a plurality of holes, one in each of the plurality of carriers, respectively arranged at aligned corners of the plurality of carriers and at least one bolt attached to an end of the threaded rod.

49. The plurality of carriers of claim 45, wherein the plurality of carriers are held together by being stacked as an integrated unit.

50. The plurality of carriers of claim 49, wherein each of the plurality of carriers comprises a plurality of protrusions on a first side of the carrier and a plurality of recesses on a second, opposite side of the carrier, wherein the protrusions are configured to engage corresponding recesses to hold the stack of carriers together as the integrated unit.

51. The plurality of carriers of claim 49, wherein each of the plurality of carriers comprises a self-aligning lip on a first side of the carrier and a recess on a second, opposite side of the carrier, wherein the recess is configured to engage the self-aligning lip to hold the stack of carriers together as the integrated unit.
